(19) United States
(12) Patent Application Publication
(10) Pub. No.: US 2008/0222495 A1
(43) Pub. Date: Sep. 11, 2008

(54) Data storage apparatus

(76) Inventor: Wei-Chi Wu, Jhubei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/068,368

(22) Filed: Feb. 6, 2008

(30) Foreign Application Priority Data
Feb. 15, 2007 (TW) 096105641

(51) Int. Cl. H03M 13/00

(52) U.S. Cl. 714/776

(57) ABSTRACT

A data storage apparatus with multiple-modes for error detecting and correcting is disclosed, comprising a controller, a data storage media, and a multiple-modes error detecting and correcting device, wherein the multiple-modes error detecting and correcting device is provided within the controller, wherein the controller further comprises a ECC register electrically connected with a codec, a status and timing controller, a error formula generator, an error position solver, and a multiple-modes adjusting controller, wherein the multiple-modes adjusting controller can be used to control the codec, the error formula generator, or the error position solver, accordingly, a final-selected-mode error detecting and correcting device can be set up, thus, the detecting circuit can be miniaturized and the detecting efficiency of the error correction code can be improved.

### FIELD OF THE INVENTION

The present invention relates to a data storage apparatus, and more particularly to a data storage apparatus with multiple-modes for error detecting and correcting, comprising a multiple-modes adjusting controller used for improving the detecting efficiency of the Error Correction Code (ECC) and miniaturizing the detecting circuit.

### BACKGROUND OF THE INVENTION

In accordance with the digital technology is progressing, most of our life information have been transformed in digital data recorded, accordingly, that can be backuped and transmitted through various interfaces, such that can be more convenient and correct for data storage. Moreover, during the data transmitting or saving, this data is unavoidable with errors occurred, generally, an Error Correcting Code (ECC) and an error detecting and correcting device are used to detect and correct the error data during transmission or storage.

Referring to FIG. 1, a data storage apparatus 100 with error detecting and correcting is shown regarding as the prior art. The apparatus 100 includes a controller 10 connected to a data storage media 16, wherein the controller 10 includes a micro controller 12 connected with a buffer 13, a host interface controller 14, a data access controller 15, and a error detecting and correcting device 20, wherein the micro controller 12 is used to control the previous mentioned function units.

The controller 10 is connected to the data storage media 16 through a data access bus 17, and the data access control 15 is used to access data from the data storage media 16. The data storage apparatus 100 can transmit data to a host system 11 through a host bus 18 and the host interface controller 14. For example, the data within the host system 11 can be transmitted to the data storage media 16 through the host bus 18, the controller 10, and the data access bus 17. As well as, the data within the data storage media 16 can be transmitted to the host system 11 through the data access bus 17, the controller 10, and the host bus 18.

During the data transmission between the host system 11 and the data storage apparatus 100, an error data is usually occurred accordingly, therefore, an ECC and a device for detecting and correcting 20 are required to detect and correct.

Referring to FIG. 2, the prior art error detecting and correcting device 20 includes a plurality of error detecting and correcting modules 21, 23, . . . , and 29, such as the first error detecting and correcting module 21, the second error detecting and correcting module 23, . . . , and the Nth error detecting and correcting module 29. However, if each error detecting and correcting module 21, 23 . . . , or 29 selects the ECC module with the same architecture, then the similar structure of both would be occurred. For example, the first error detecting and correcting module 21 includes a first ECC register 211 respectively connected with a first codec 212, a first status and timing controller 213, a first error formula generator 214, a first error position solver 215, and a first error corrector 216, as well as, the second error detecting and correcting module 23 . . . , and the Nth error detecting and correcting module 29 are with the corresponding elements therein.

Nevertheless, since the data storage media 16 is with different characteriscs or properties, the error detecting and correcting module 21, 23 . . . , and 29 used to code, decode, error detect and correct should be different and corresponding. For example, if the data storage media is with the first module, the first error detecting and correcting module 21 would be used to code, decode, error detect and correct.

Therefore, while the material of the data storage media 16 is decided, an appropriate error detecting and correcting module is going to be selected as well for going to code, decode, error detect and correct. However, if the first error detecting and correcting module 21 is selected, then the other error detecting and correcting modules 23 . . . , and 29 would be abandoned, such that the error detecting circuit within the error detecting and correcting device 20 cannot advantage for miniaturizing relatively.

### SUMMARY OF THE INVENTION

A novel data storage apparatus is disclosed. The data storage apparatus is with higher efficiency on the fields of coding, decoding, error detecting, and error correcting, furthermore, the size of that can be miniaturized.

It is a primary objective of the present invention to provide a data storage apparatus that comprises a multiple-modes error detecting and correcting device having a multiple-modes adjusting controller therein, wherein the multiple-modes adjusting controller can be used to set up a final-selected-mode error detecting and correcting device that is supportable with a data storage media, such that the advantage for miniaturizing the circuit size of elements can be provided.

It is a secondary objective of the present invention to provide a data storage apparatus that comprises a multiple-modes error detecting and correcting device being used for improving the detecting efficiency of the ECC according to module switching by the multiple-modes error detecting and correcting device.

To achieve the previous mentioned objects, the present invention provides a data storage apparatus, comprising a controller having a micro controller electrically connected with a buffer, a host interface controller, and a data access controller respectively, wherein the controller is connected to a host system through the host interface controller; a data storage media connected to the data access controller within the controller; and a multiple-modes error detecting and correcting device provided within the controller and electrically connected to the micro controller, wherein the multiple-modes error detecting and correcting device comprising a ECC register electrically connected with a codec, a status and timing controller, an error formula generator, an error position solver, and a multiple-modes adjusting controller, wherein the multiple-modes adjusting controller can be used to selectively control one of the codec, the error formula generator, and the error position solver to set up a final-selected-mode error detecting and correcting device accordingly that is supportable with the data storage media.

### BRIEF DESCRIPTION OF THE DRAWINGS

It will be understood that the figures are not to scale since the individual layers are too thin and the thickness differences of various layers too great to permit depiction to scale.

FIG. 1 is a block diagram of a prior art disclosing a data storage apparatus with error detecting and correcting function;

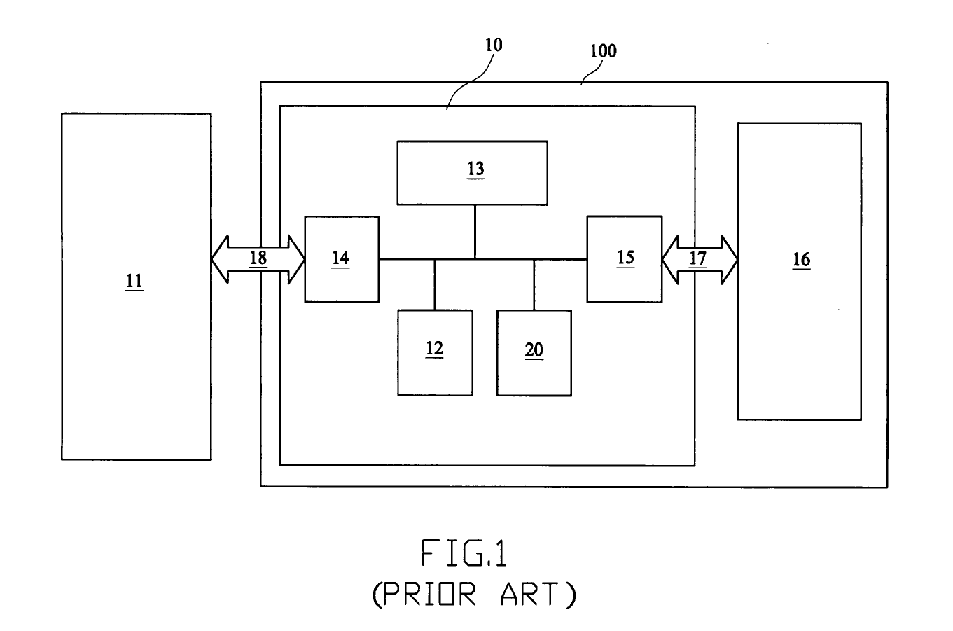

FIG. 2 is a block diagram of the prior art disclosing an error detecting and correcting device;

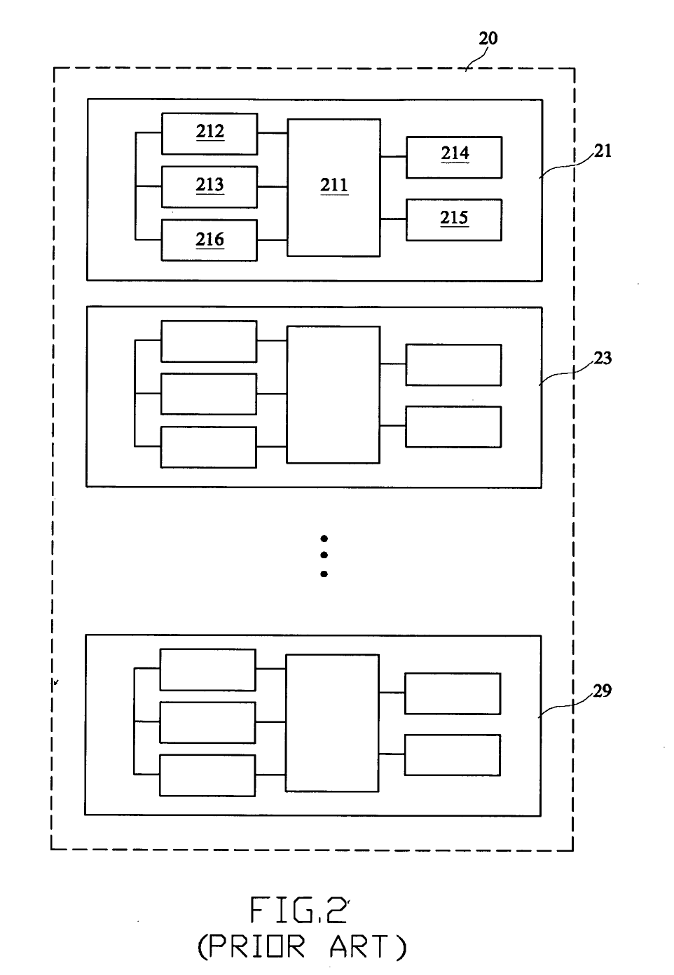

FIG. 3 is a block diagram of a preferred embodiment of the present invention disclosing a data storage apparatus with multiple-modes for error detecting and correcting;

FIG. 4 is a block diagram of the preferred embodiment of the present invention disclosing a multiple-modes error detecting and correcting device;

FIG. 5 is a block diagram of the preferred embodiment of the present invention disclosing a codec;

FIG. 6 is a block diagram of the preferred embodiment of the present invention disclosing an error formula generator; and

FIG. 7 is a block diagram of the preferred embodiment of the present invention disclosing an error position solver.

### DETAILED DESCRIPTION OF THE INVENTION

The structural features and the effects to be achieved may further be understood and appreciated by reference to the presently preferred embodiments together with the detailed description.

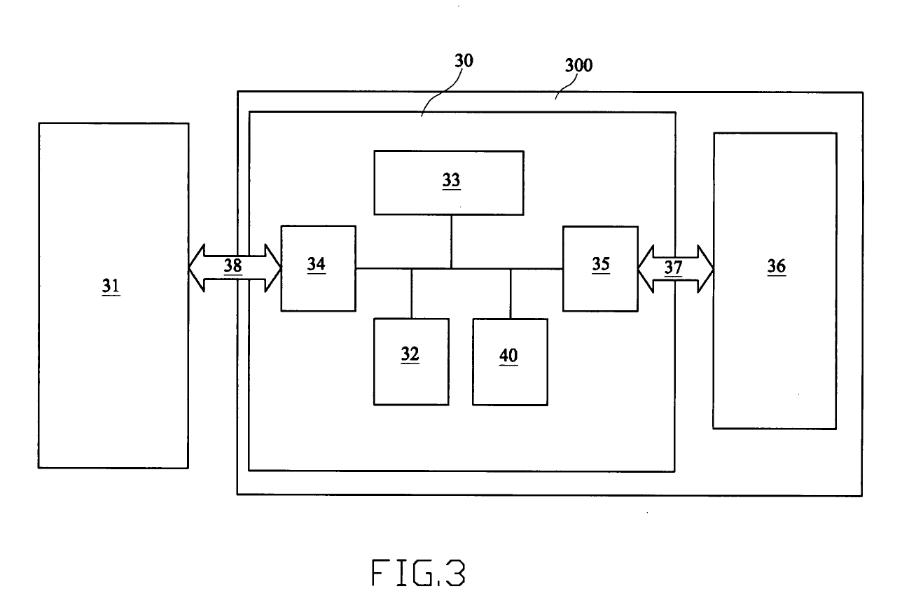

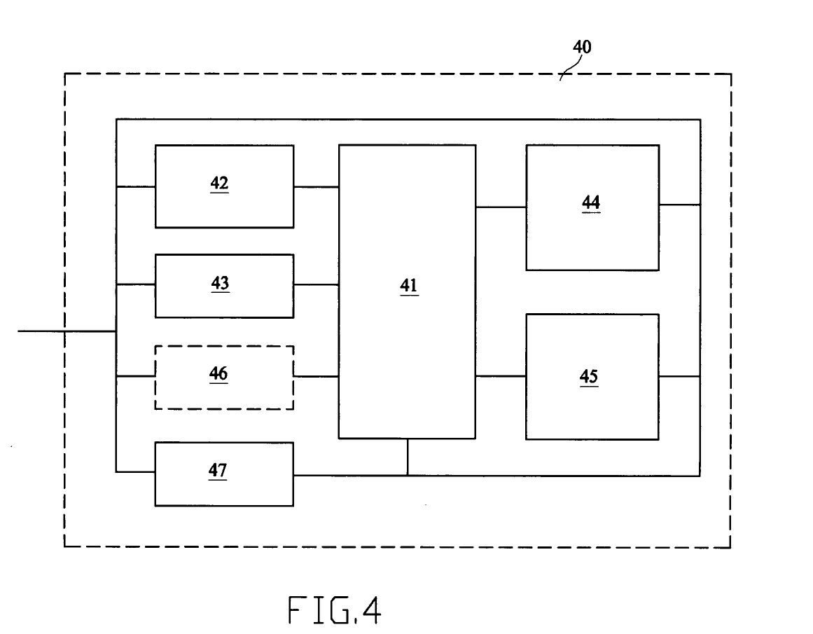

Referring to FIG. 3 and FIG. 4, a data storage apparatus with multiple-modes for error detecting and correcting and an error detecting and correcting device are disclosed regarding a preferred embodiment of the present invention. As shown on Figures, the data storage apparatus 300 comprises a controller 30 connected to a data storage media 36, wherein the controller 30 comprises a micro controller 32 that is used to control a buffer 33, a host interface controller 34, data access controller 35, and an multiple-modes error detecting and correcting device, wherein these elements are connected respectively to the micro controller 32.

The controller 30 is connected to the data storage media 36 through a data access bus 37. The data access controller 35 is used to access data from the data storage media 36. The data storage apparatus 300 is connected to a host system 31 through a host bus 38 and the host interface controller 34 for data access and transmission.

The host interface controller 34 is used for decoding the protocol command and the data transmitted from the hot system 31, thereafter, the decoded protocol command will be transmitted to the micro controller 32 that would access and transmit data according to the processing of the buffer 33, the data access controller 35, the data access bus 37, the data storage media 36, and the multiple-modes error detecting and correcting device 40.

While a write command is transmitted by the host system 31, the data for writing will be transmitted and stored within the buffer 33 through the host bus 38 and the host interface controller 34, accordingly, the multiple-modes error detecting and correcting device 40 will generate a ECC-PARITY according to the coding of ECC, and then, the ECC-PARITY and the data for storing will be transmitted and stored into the Logic Block Address (LBA) indicated by the data storage media 36 through the data access controller 35, the data access bus 37, wherein the multiple-modes error detecting and correcting device has been set to be the error detecting and correcting device with appropriate module.

While a read command is transmitted by the host system 31, the micro controller 32 will command the data access controller 35 to read data from the LBA indicated by the data storage media 36 to the buffer 33 through the data access bus 37, thereafter, the read data and the corresponding ECC-PARITY will be transmitted to the error detecting and correcting device 40 with multiple-modes for processing further error detecting and correcting, wherein the error detecting and correcting device 40 with multiple-modes is adjusted to be the error detecting and correcting device 40 with the appropriate module. Consequently, after detecting and correcting, the data for reading will be transmitted to the host system 31 through the host interface controller 34 and the host bus 38.

As shown on FIG. 4, the multiple-modes error detecting and correcting device 40 of the present invention comprises a ECC register 40 electrically connected with a codec 42, a status and timing controller 43, an error formula generator 44, an error position solver 45, and a multiple-modes adjusting controller 47. The multiple-modes adjusting controller 47 is used to adjust the codec 42, the error formula generator 44, and/or the error position solver 45 to adjust and set the multiple-modes error detecting and correcting device 40 to be an appropriate final-selected-mode error detecting and correcting device accordingly that is supportable with the data storage media 36. In another word, the module of the multiple-modes error detecting and correcting device 40 is adjusted and set by the multiple-modes adjusting controller 47 to fit for the data storage media 36, accordingly, the ECC detecting is processing further.

Due to the another embodiment of the present invention, the multiple-modes error detecting and correcting device 40 further comprises an error corrector 46 electrically connected to the ECC register 41 as well, accordingly, the error corrector can be adjusted by the multiple-modes adjusting controller 47 and used to correct error data.

Practically, the paths of data transmission between the host system 31 and the data storage apparatus 300 can be indicated obviously, one of which is the path of data transmission from the host system 31 to the data storage apparatus 300, another of which is the path of data transmission from the data storage apparatus 300 to the host system 31. The following description discloses the operation of the multiple-modes error detecting and correcting device through these two paths.

As the host system 31 is going to write data to the data storage apparatus 300, the write command and write data will be transmitted to the host interface controller 34 through the host bus 38, wherein the host interface controller 34 is provided within the controller 30 of the data storage apparatus 300. The host interface controller 34 will decode the write command and further notice the micro controller 32, and the write data stored in the buffer 33 can be written into the LBA indicated by the data storage media 36 through the data access controller 35 and the data access bus 37. Concurrently, the codec 42 will encode the write data that is going to be written into the data storage media 36, wherein the codec 42 is provided within the multiple-modes error detecting and correcting device that has been adjusted and set for the appropriate module thereof. During the encoding process, the ECC register 41 will be used to assist to encode as well, accordingly, this encoding process means to encode the ECC-PARITY that is corresponding with the data which is going to be stored. Thus, the ECC-PARITY will be written into the data storage media 36 with following the stored data. Accordingly, this ECC-PARITY written into the data storage media 36 can be used to be as a reference for encoding the ECC while the stored data has to be read thereafter.

On the contrary, as the data stored in the data storage media 300 is going to be read and transmitted to the host system 31, the controller 30 will receive the digital information and the ECC-PARITY stored in the data storage media 36, accordingly, the codec 42 will be used to decode, wherein the codec 42 is provided within the multiple-modes error detecting and correcting device that has been adjusted and set for the appropriate module thereof. And, once there is an error data occurred, the status and timing controller 43 will enable the error formula generator 44 and the error position solver 45, and operate the error formula and solve the error position according to the appropriate module has been adjusted and set. Consequently, after solving the error position, such error data stored in the buffer 33 will be corrected and further transmitted to the host system 31 through the host interface controller 34 and the host bus 38.

After decoding the data read from the data storage media 36, once there is an error data occurred, the error formula generator 44 will operate the decoded data which is call the Syndromes, and then, an Error Locator Polynomial will be solved for detecting the error data read from the data storage media 36. The error position solver 45 will solve the error position according to the error formula, and the error corrector 46 will correct the error data. Certainly, if there is without any error data occurred, the data will be directly transmitted to the host system 31 from the buffer 33 through the host interface controller 34 and the host bus 38.

The multiple-modes adjusting controller 47 is used to selectively switch the modules of the codec 42, the error formula generator 44, and/or the error position solver 45 to set up an appropriate final-selected-mode error detecting and correcting device 40 accordingly that is supportable with the data storage media 36. Specifically, the multiple-modes adjusting controller 47 can be used to selectively switch the modules of the codec 42, the error formula generator 44, and/or the error position solver 45 according to the micro controller 32 and the firmware operated by that, the command from the host system 31, the data format of the data stored in the data storage media 36 to set up an appropriate final-selected-mode error detecting and correcting device 40 accordingly that is supportable with the data storage media 36.

Additionally, the codec 42 can be used to a decoder, a coder, or a combination thereof during the data transmission between the host system 31 and the data storage apparatus 300. And, the data storage media 36 disclosed on the present invention is selectively as one of a flash memory, an EEPROM, a magnetic recording media, and/or a laser recording media.

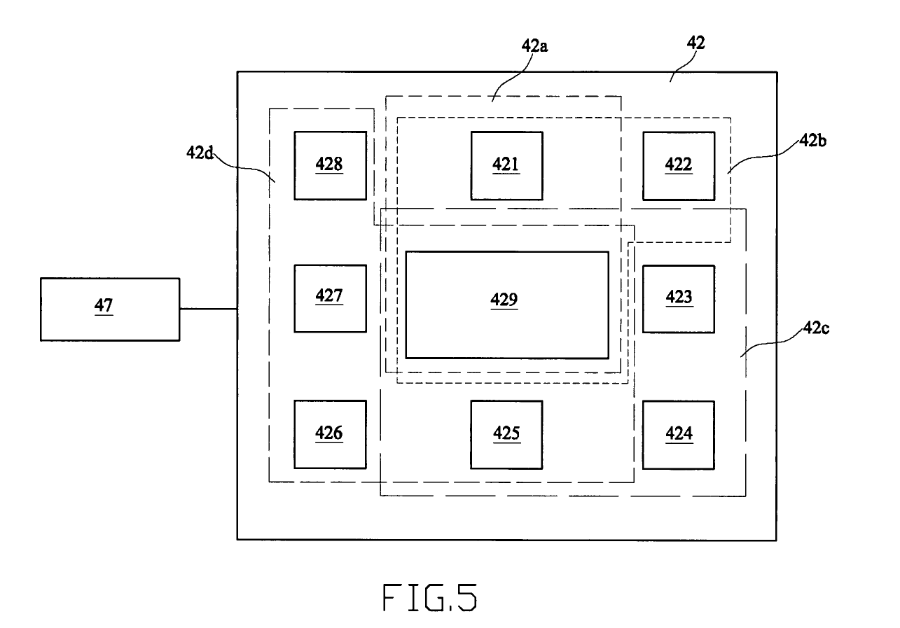

Referring to FIG. 5, a codec is shown on the block diagram of the preferred embodiment of the present invention. As shown on FIG. 4 and FIG. 5, the codec 42 is electrically connected to the multiple-modes adjusting controller 47. The codec 47 comprises a common codec circuit 429 and a plurality of peripheral codec circuit, such as the first peripheral codec circuit 421, the second peripheral codec circuit 422, the third peripheral codec circuit 423, the fourth peripheral codec circuit 424, the fifth peripheral codec circuit 425, the sixth peripheral codec circuit 426, the seventh peripheral codec circuit 427, and the eighth peripheral codec circuit 428. Therefore, one of those peripheral codec circuits will be selected by the multiple-modes adjusting controller 47 to collocate with the common codec circuit 429, such that the codec 42 can be an appropriate module codec 42, an appropriate module coder, or an appropriate module decoder.

Furthermore, the multiple-modes adjusting controller 47 can be used to select the peripheral codec circuits 421, 422, . . . , and 428 to collocate with the common codec circuit 49 according to the micro controller 32 and the firmware operated by that, the command from the host system 31, the data format of the data stored in the data storage media 36 to be one module codec for being collocated to set up the final-selected-mode error detecting and correcting device 40. Specifically, the multiple-modes adjusting controller 47 can be used to select the first peripheral codec circuit 421 to collocate with the common codec circuit 429 for being the first module codec 42a, select the first peripheral codec circuit 421 and the second peripheral codec circuit 422 to collocate with the common codec circuit 429 for being the second module codec 42b, select the third peripheral codec circuit 423 and the fourth peripheral codec circuit 424 to collocate with the common codec circuit 429 for being the third module codec 42c, and select the fifth peripheral codec circuit 425, the sixth peripheral codec circuit 426, the seventh peripheral codec circuit 427, and the eighth peripheral codec circuit 428 to collocate with the common codec circuit 429 for being the fourth module codec 42d.

Practically, the numbers of the peripheral codec circuit are not limited which can be required for demand, such that the numbers of which can be more than eight. As well as, the modules of codec are not limited in four modules according to the selection and collocation of the peripheral codec circuits and the common codec circuit 429, such as the first module codec 42a, the second module codec 42b, the third module codec 42c, and the fourth module codec 42d. In fact, the common codec circuit 429 and the peripheral codec circuits are the circuit sets that consist of a plurality of elements.

In accordance with another embodiment of the present invention, the codec 42 can be as a single coder or a single decoder, as well as, the common codec circuit 42 and the peripheral codec circuits can be as a single common coder, a single peripheral coder, a single common decoder, and a single peripheral decoder.

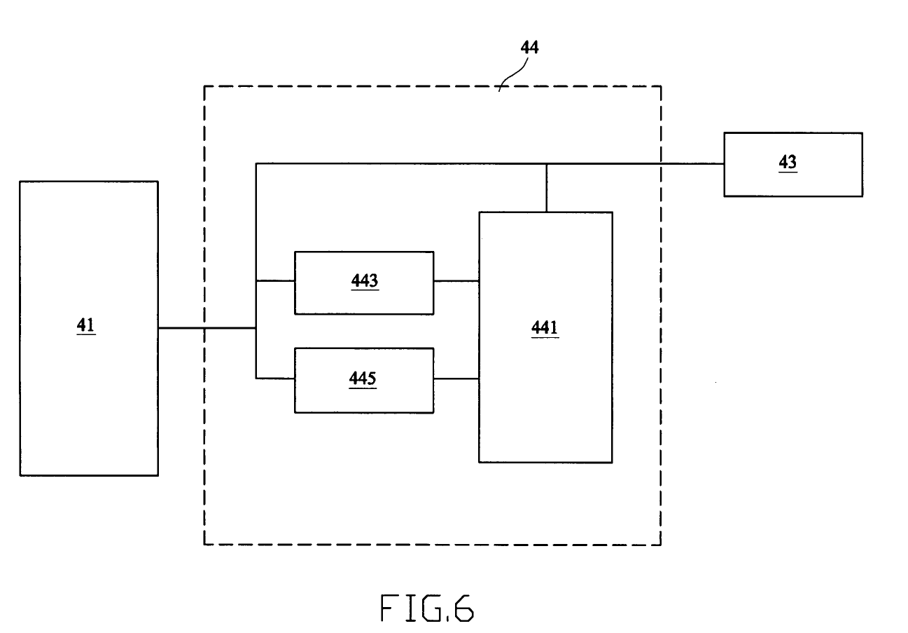

Referring to FIG. 6, an error formula generator of the preferred embodiment of the present invention is shown. As shown on FIG. 4 and FIG. 6, the error formula generator 44 is electrically connected with the status and timing controller 43 and the multiple-modes adjusting controller 47. The error formula generator 44 comprises an error formula operation circuit 441, a input-signals logic circuit 443, and a output-signals logic circuit 445. A timing sequence and an initial value issued from the status and timing controller 43 can be used for switching of the error formula generator 44 that can be resulted as an appropriate module error formula generator 44, such that a final-selected-mode error detecting and correcting device 40 can be set up accordingly, wherein the final-selected-mode error detecting and correcting device 40 is supportable with the data storage media 36.

Specifically, the status and timing controller 43 can be used to issue various timing sequences and initial values according to the micro controller 32 and the firmware operated by that, the command from the host system 31, the data format of the data stored in the data storage media 36, such that the error formula generator 44 can be resulted as an appropriate module error formula generator 44, and a final-selected-mode error detecting and correcting device 40 can be set up accordingly that is supportable with the data storage media 36.

The error formula operation circuit 411 is used for logic operation, and the input-signals logic circuit 443 is used to register the data that is required to be stored in the ECC register temporarily during the operation; the output-signals logic circuit 445 is used to read data that is registered in the ECC register during the operation. That is, the input-signals logic circuit 443 and the output-signals logic circuit 445 can be used to access data stored in the ECC register 41 during the operation of the error formula operation circuit 441, such that the operation efficiency can be improved according to the assistant of the ECC register 41 during the operation.

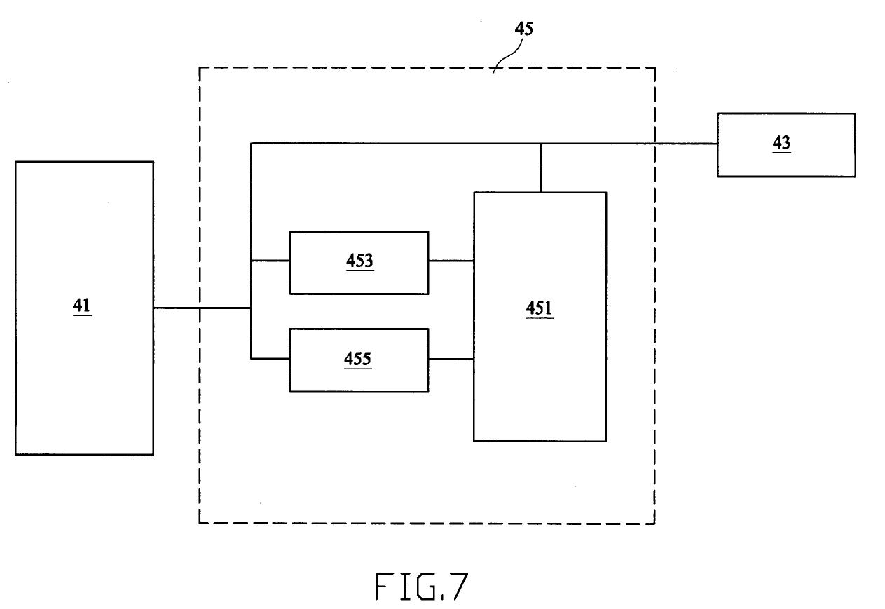

Referring to FIG. 7, an error position solver of the preferred embodiment of the present invention is shown. As shown on FIG. 4 and FIG. 7, the error position solver 45 is electrically connected with the status and timing controller 43 and multiple-modes adjusting controller 47. The error position controller 45 comprises an error position operation circuit 451, a input-signals logic circuit 453, and a output-signals logic circuit 455. A timing sequence and an initial value issued from the status and timing controller 43 can be used for switching of the error position solver 45 that can be resulted as an appropriate module error position solver 45, such that a final-selected-mode error detecting and correcting device 40 can be set up accordingly. As well as, the operation of the error position solver 45 is similar with the error formula generator 44; similarly, the operation efficiency can be improved as well.

While this invention has been described with reference to illustrative embodiments, this description is not intended to be construed in a limiting sense. Various modifications of the illustrative embodiments, as well as other embodiments of the invention, which are apparent to persons skilled in the art to which the invention pertains are deemed to lie within the spirit and scope of the invention.

I claim:

1. A data storage apparatus, comprising:
a controller comprising a micro controller electrically connected with a buffer, a host interface controller, and a data access controller respectively, wherein said controller is connected to a host system through said host interface controller;
a data storage media connected to said data access controller within said controller; and
a multiple-modes error detecting and correcting device provided within said controller and electrically connected to said micro controller, wherein said multiple-modes error detecting and correcting device comprising a ECC register electrically connected with a codec, a status and timing controller, an error formula generator, an error position solver, and a multiple-modes adjusting controller, wherein said multiple-modes adjusting controller can be used to selectively control one of said codec, said error formula generator, and said error position solver to set up a final-selected-mode error detecting and correcting device accordingly that is supportable with said data storage media.

2. The data storage apparatus of claim 1, further comprising a data error corrector provided within said multiple-modes error detecting and correcting device and connected to said ECC register.

3. The data storage apparatus of claim 1, wherein said codec comprises a common codec circuit and a plurality of peripheral codec circuits, wherein said multiple-modes error detecting and correcting device can be used to selectively control at least one peripheral codec circuit electrically connecting to said common codec circuit to become as one module codec, wherein said final-selected-mode error detecting and correcting device is set up according to the collocation thereof.

4. The data storage apparatus of claim 1, wherein said error formula generator comprises a input-signals logic circuit, a output-signals logic circuit, and an error formula operation circuit respectively connected to said status and timing controller, wherein said error formula generator can be one module error formula generator since said status and timing controller is used to transmit a timing sequence and a initial value, wherein said final-selected-mode error detecting and correcting device is set up according to the collocation thereof.

5. The data storage apparatus of claim 1, wherein said error position solver comprises a input-signals logic circuit, a output-signals logic circuit, and an error formula operation circuit respectively connected to said status and timing controller, wherein said error position solver can be one module error position solver since said status and timing controller is used to transmit a timing sequence and a initial value, wherein said final-selected-mode error detecting and correcting device is set up according to the collocation thereof.

6. The data storage apparatus of claim 1, wherein said multiple-modes adjusting controller can be used to set up said multiple-modes error detecting and correcting device according to said micro controller and the firmware operated by that.

7. The data storage apparatus of claim 1, wherein said multiple-modes adjusting controller can be used to set up said multiple-modes error detecting and correcting device according to the command operated by said host system.

8. The data storage apparatus of claim 1, wherein said multiple-modes adjusting controller can be used to set up said multiple-modes error detecting and correcting device according to the data accessing from said data storage media.

9. The data storage apparatus of claim 1, wherein said codec can be selectively as one of a coder, a decoder, and a combination thereof.

10. The data storage apparatus of claim 1, wherein said codec is a coder, comprising a common code circuit and a plurality of peripheral code circuits, wherein said multiple-modes adjusting controller can be used to selectively control at least one peripheral code circuit to electrically connect with said common code circuit, wherein said multiple-modes adjusting controller is resulted as one module coder, wherein said final-selected-mode error detecting and correcting device is set up according to the collocation thereof.

11. The data storage apparatus of claim 1, wherein said codec is a decoder, comprising a common decode circuit and a plurality of peripheral decode circuits, wherein said multiple-modes adjusting controller can be used to selectively control at least one peripheral decode circuit to electrically connect with said common decode circuit, wherein said multiple-modes adjusting controller is resulted as one module decoder, wherein said final-selected-mode error detecting and correcting device is set up according to the collocation thereof.

12. The data storage apparatus of claim 1, wherein said data storage media can be selectively as one of a flash memory, an EEPROM, a magnetic recording media, a laser optical recording media, and a combination thereof.
